(19) United States
(12) Patent Application Publication
(10) Pub. No.: US 2008/0106881 A1
(43) Pub. Date: May 8, 2008

(54) Active signal cross-connect system

(75) Inventors: Gabor Tari, Budapest (HU); Ferenc Boka, Budapest (HU); Dominic J. Louwagie, Eden Prairie, MN (US); Alejandro Mejia De Avila, Juarez Chi (MX); Luis Lorenzo Balandran, Juarez CD. Juarez Chi (MX)

Correspondence Address: MERCHANT & GOULD PC, P.O. BOX 2903, MINNEAPOLIS, MN, 55402-0903, US

(73) Assignee: ADC Telecommunications, Inc., Eden Prairie, MN (US)

(21) Appl. No.: 11/897,954

(22) Filed: Aug. 31, 2007

Related U.S. Application Data
(60) Provisional application No. 60/842,178, filed on Sep. 1, 2006.

(51) Int. Cl. H05K 7/04

(52) U.S. Cl. 361/807

(57) ABSTRACT

A telecommunications system includes a chassis having a front side and a rear side and a plurality of jacks mounted to the chassis. Each jack includes an IN port, an OUT port and a MONITOR port. A cross-connect panel including an array of cross-connect connection locations is accessible from the front side of the chassis. An optical multiplexer housed within the chassis is electrically connected to the jacks by circuitry within the chassis. The multiplexer is configured to multiplex a plurality of IN electrical signals that are going away from the jacks toward a piece of telecommunications equipment to an IN optical signal and is configured to split an OUT optical signal that is going away from the piece of telecommunications equipment toward the jacks to a plurality of OUT electrical signals, wherein the IN electrical signals and the OUT electrical signals can be monitored by inserting plugs into the MONITOR ports of the jacks.

### CROSS-REFERENCE TO RELATED APPLICATIONS

This application claims the benefit of U.S. Provisional Application No. 60/842,178, filed on Sep. 1, 2006, which application is incorporated herein by reference.

### TECHNICAL FIELD

The principles disclosed herein relate generally to digital signal cross-connect systems.

### BACKGROUND

A digital signal cross-connect system (DSX) provides a location for interconnecting two digital transmission paths. The apparatus for a DSX is located in one or more frames, or bays, usually in a telephone central office. The DSX apparatus also provides jack access to the transmission paths.

DSX jacks are well known and typically include a plurality of bores sized for receiving tip-and-ring plugs. A plurality of spring contacts are provided within the bores for contacting the tip-and-ring plugs. The jacks are typically electrically connected to digital transmission lines, and are also electrically connected to a plurality of wire termination members used to cross-connect the jacks. By inserting plugs within the bores of the jacks, signals transmitted through the jacks can be interrupted or monitored.

FIG. 1 schematically illustrates a DSX system that is an example of the type found at a telephone service provider's central office. The DSX system is shown including three DSX jacks 10a, 10b and 10c. Each DSX jack 10a, 10b and 10c is connected to a specific piece of digital equipment. For example, jack 10a is shown connected to digital switch 12, jack 10b is shown connected to office repeater 14a, and jack 10c is shown connected to office repeater 14b. Each piece of digital equipment has a point at which a digital signal can enter, as well as a point at which the digital signal can exit. The jacks 10a, 10b and 10c each include OUT termination pins 16 and IN termination pins 18. The DSX jacks 10a, 10b and 10c are connected to their corresponding pieces of digital equipment by connecting the OUT termination pins 16 to the signals exiting the equipment (i.e., going toward the DSX system) and the IN termination pins 18 to the signals entering the equipment (i.e., going away from the DSX system).

Referring still to FIG. 1, jacks 10a and 10b are “cross-connected” to one another by semi-permanent connections. The semi-permanent connections extend between cross-connect fields 19 of the jacks 10a and 10b. For example, wires 20 connect OUT cross-connect pins of jack 10a to IN cross-connect pins of jack 10b. Similarly, wires 21 connect IN cross-connect pins of jack 10a to OUT cross-connect pins of jack 10b. The jacks 10a and 10b are preferably normally closed. Thus, in the absence of a plug inserted within either of the jacks 10a and 10b, an interconnection is provided between the jacks 10a and 10b and therefore between digital switch 12 and office repeater 14a.

The semi-permanent connection between the digital switch 12 and the office repeater 14a can be interrupted for diagnostic purposes by inserting plugs within the IN or OUT ports of the jacks 10a and 10b. Likewise, patch cords can be used to interrupt the semi-permanent connection between the jacks 10a and 10b to provide connections with other pieces of digital equipment. For example, the digital switch 12 can be disconnected from the office repeater 14a and connected to the office repeater 14b through the use of patch cords 23. The patch cords 23 include plugs that are inserted within the IN and OUT ports of the jack 10a and the IN and OUT ports of the jack 10c. By inserting the plugs within the IN and OUT ports of the jack 10a, the normally closed contacts are opened, thereby breaking the electrical connection with the office repeater 14a and initiating an electrical connection with office repeater 14b.

The jacks 10a, 10b and 10c are shown to also include integral monitor ports for allowing signals to be monitored without interrupting the signal transmissions.

### SUMMARY

According to one particular aspect, the principles disclosed herein relate to a digital signal cross-connect system (DSX) that includes an active signal cross-connect (ASX) system including DSX jacks connected to a telecommunications equipment through a multiplexer unit wherein electrical signals are converted by the multiplexer unit to digital/optical signals and vice versa.

According to another particular aspect, the disclosure herein relates to a telecommunications system that includes a chassis having a front side and a rear side and a plurality of jacks mounted to the chassis. Each jack includes an IN port, an OUT port and a MONITOR port. A cross-connect panel including an array of cross-connect connection locations is accessible from the front side of the chassis. An optical multiplexer housed within the chassis is electrically connected to the jacks by circuitry within the chassis. The multiplexer is configured to multiplex a plurality of IN electrical signals that are going away from the jacks toward a piece of telecommunications equipment to an IN optical signal and is configured to split an OUT optical signal that is going away from the piece of telecommunications equipment toward the jacks to a plurality of OUT electrical signals, wherein the IN electrical signals and the OUT electrical signals can be monitored by inserting plugs into the MONITOR ports of the jacks.

A variety of additional inventive aspects will be set forth in the description that follows. The inventive aspects can relate to individual features and combinations of features. It is to be understood that both the foregoing general description and the following detailed description are exemplary and explanatory only and are not restrictive of the broad inventive concepts upon which the embodiments disclosed herein are based.

### BRIEF DESCRIPTION OF THE DRAWINGS

The accompanying drawings, which are incorporated in and constitute a part of the description, illustrate several aspects of the invention and together with the description, serve to explain the principles of the invention. A brief description of the drawings is as follows:

FIG. 1 is a schematic diagram of a prior art DSX system;

FIG. 2 is a schematic diagram of an active signal cross-connect (ASX) system having features that are examples of inventive aspects in accordance with the principles of the present disclosure;

FIG. 3 is a front perspective view of a chassis housing the ASX system diagrammatically shown in FIG. 2;

FIG. 4 shows a partially exploded perspective view of the chassis of FIG. 3, illustrating the connections between the multiplexer and the front fiber optic adapters;

FIG. 5 is a front plan view of the chassis of FIG. 3;

FIG. 6 is a right side plan view of the chassis of FIG. 3;

FIG. 7 is a left side plan view of the chassis of FIG. 3;

FIG. 8 is a top plan view of the chassis of FIG. 3;

FIG. 9 is a bottom plan view of the chassis of FIG. 3;

FIG. 10 is a rear perspective view of the chassis of FIG. 3;

FIG. 11 is a rear plan view of the chassis of FIG. 3;

FIG. 12 is a rear plan view of the chassis of FIG. 3, wherein portions of the rear cover have been broken away to show the interior of the chassis;

FIG. 13 is a diagrammatic view illustrating the chassis of FIG. 3 from a top view thereof, the chassis shown with the top cover of the chassis removed, illustrating the connections between the front jacks and the multiplexer;

FIG. 14 is a front perspective view of a jack configured to be received within the chassis of FIG. 3;

FIG. 15 is a rear perspective view of the jack of FIG. 12;

FIG. 16 is an exploded front perspective view of a jack mount and twisted pair rear interface assembly configured to be received within the chassis of FIG. 3, the jack mount configured to receive the jack of FIG. 14;

FIG. 17 is an exploded rear perspective view of the jack mount and twisted pair rear interface assembly of FIG. 16;

FIG. 18 is a side assembled view of the jack mount and twisted pair rear interface assembly of FIG. 16;

FIG. 19 is a schematic circuit diagram corresponding to the jack mount and twisted pair rear interface assembly of FIG. 16;

FIG. 20 is a front plan view another embodiment of a chassis configured to house the ASX system diagrammatically shown in FIG. 2, the chassis shown with one of the front covers open to expose one of the cross-connect fields;

FIG. 21 is a left side diagrammatic view of the chassis of FIG. 20; and

FIG. 22 is a diagrammatic view illustrating the chassis of FIG. 20 from a top view thereof, the chassis shown with the top cover of the chassis removed, illustrating the connections among the front jacks, the cross-connect fields, and the multiplexer.

### DETAILED DESCRIPTION

Reference will now be made in detail to exemplary inventive aspects of the present disclosure which are illustrated in the accompanying drawings. Wherever possible, the same reference numbers will be used throughout the drawings to refer to the same or like parts.

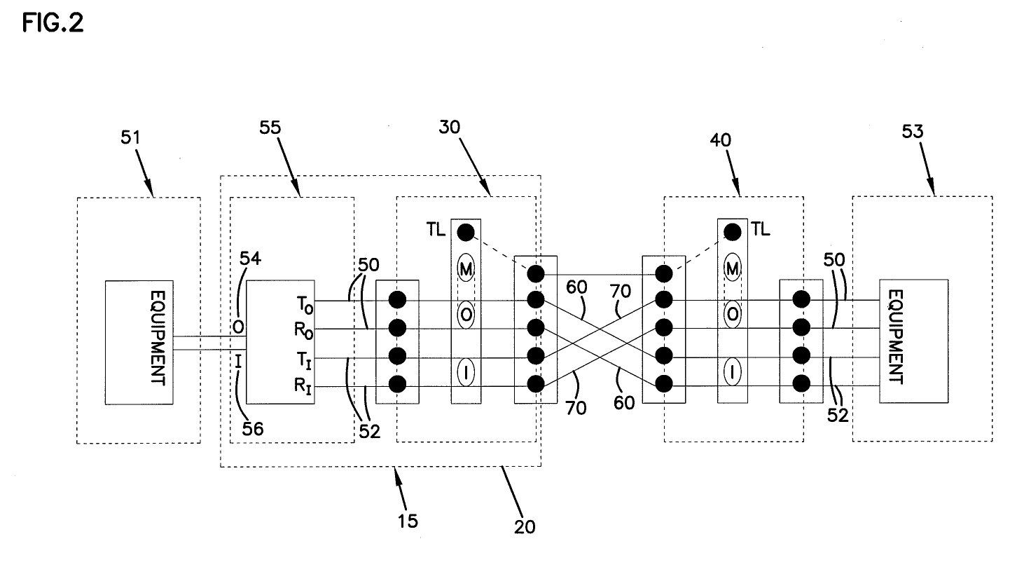

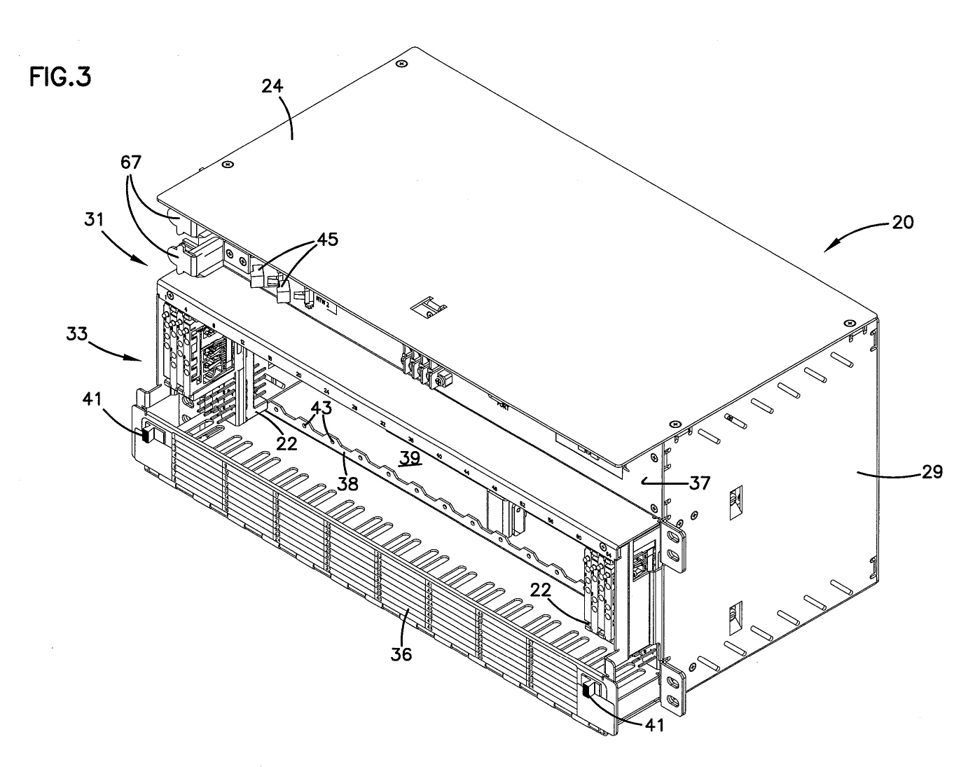

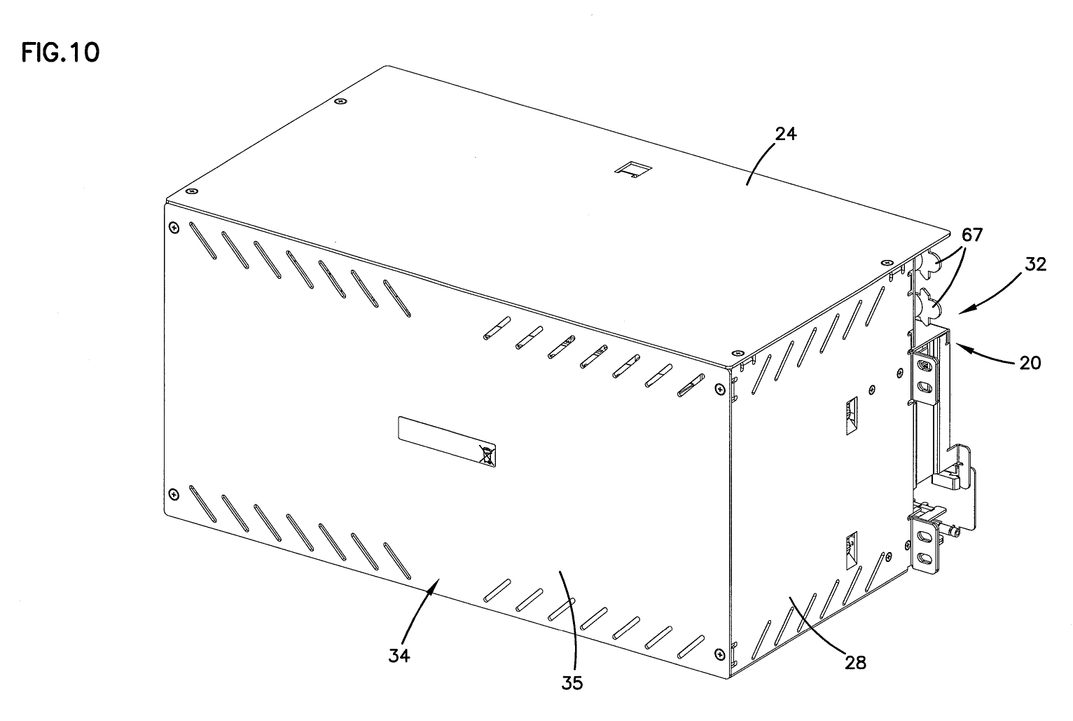

FIG. 2 schematically illustrates an active signal cross-connect (ASX) system 15 having features that are examples of inventive aspects in accordance with the principles of the present disclosure. The ASX system 15 includes a first plurality of DSX jacks 30 connected to a multiplexer unit 55 housed in the same chassis 20 as DSX jacks 30 (see FIGS. 3-11). The multiplexer 55 of the ASX system 15 is connected to a first telecommunications equipment 51. The first plurality of jacks 30 of the ASX system 15 are cross-connected to a second plurality of DSX jacks 40. The second plurality of DSX jacks 40 are connected to a second telecommunications equipment 53. It should be noted that, for ease of illustration, only a single jack 30 and a single jack 40 has been shown diagrammatically in FIG. 2.

Still referring to FIG. 2, each piece of telecommunications equipment (e.g., the first telecommunications equipment 51, the second telecommunications equipment 53, and the multiplexer 55) has a point at which a digital signal can enter, as well as a point at which the digital signal can exit. The DSX jacks 30 and 40 each include OUT termination pins 50 and IN termination pins 52 for connection to various equipment.

The DSX jack 40 is connected to the second telecommunications equipment 53 by connecting the OUT termination pins 50 to the signals exiting the equipment 53 (i.e., going toward the DSX system) and the IN termination pins 52 to the signals entering the equipment 53 (i.e., going away from the DSX system).

The DSX jack 30 is connected to the multiplexer 55 by connecting the OUT termination pins 50 to the signals exiting the multiplexer 55 (i.e., going toward the DSX system) and the IN termination pins 52 to the signals entering the multiplexer 55 (i.e., going away from the DSX system).

The multiplexer 55 converts the electrical IN signals of the termination pins 52 (TI and RI signals going away from the DSX jack 30 into the equipment 51) to a digital/optical IN signal 56. The multiplexer 55 splits the digital/optical OUT signal 54 (signal going away from the equipment 51 toward the DSX jack 30) to electrical OUT signals to be carried by the termination pins 50 (TO and RO) of the jack 30. In certain embodiments, the multiplexer 55 is configured to convert 2 Megabit copper signals to multiplexed 155 Megabit fiber optic signals.

Referring still to FIG. 2, jacks 30 and 40 are cross-connected to one another. The connections extend between cross-connect fields of the jacks 30 and 40. For example, wires 60 connect OUT cross-connect pins of jack 30 to IN cross-connect pins of jack 40. Similarly, wires 70 connect IN cross-connect pins of jack 30 to OUT cross-connect pins of jack 40. The jacks 30 and 40 may be normally closed. Thus, in the absence of a plug inserted within either of the jacks 30 and 40, an interconnection is provided between the jacks 30 and 40 and therefore between the first telecommunications equipment 51 and the second telecommunications equipment 53, the first telecommunications equipment 51 being connected to the ASX system 15 through the multiplexer 55.

The connection between the first telecommunications equipment 51 and the second telecommunications equipment 53 can be interrupted for diagnostic purposes by inserting plugs within the IN or OUT ports of the jacks 30 and 40. Also, the connection between the first telecommunications equipment 51 and the second telecommunications equipment 53 can be non-intrusively monitored by inserting plugs within the MON ports of the jacks 30 and 40.

FIGS. 3-13 illustrate an embodiment of the chassis 20 for housing a plurality of the jacks 30 and also the multiplexer unit 55. The jacks 30 are housed in jack mounts 22 that are inserted into the chassis 20. For clarity, only two jack mounts 22 are shown in FIGS. 3-5. Each jack mount 22, as depicted, is configured to hold four jacks (i.e., two odd jacks and two even jacks, positioned in an alternating fashion). However, it will be appreciated that the chassis 20 is adapted for housing a plurality of jack mounts 22. In the depicted embodiment, to conform with conventional international standards, the chassis 20 can house sixteen jack mounts 22 and have a length of about nineteen inches. Alternatively, in other embodiments, in accordance with standard United States specifications, the chassis 20 could be configured to house twenty-one jacks and have a length of about twenty-three inches. Of course, other sizes and numbers of jack mounts could also be used.

In an embodiment, wherein the chassis is configured to house sixty-four DSX jacks 30, the multiplexer 55 is configured to multiplex sixty-four IN copper signals to one IN fiber optic signal (IN signal is referring to a signal going away from the DSX jack to the equipment) and is configured to split one OUT fiber optic signal to sixty-four OUT copper signals (OUT signal is referring to a signal going away from the equipment to the DSX jack).

The chassis 20 includes a top plate 24 positioned opposite from a bottom plate 26. The top and bottom plates 24 and 26 are interconnected by left and right side plates 28 and 29. The chassis 20 also includes a front side 32 positioned opposite from a back side 34. The back side 34 of the chassis is covered by a rear plate 35.

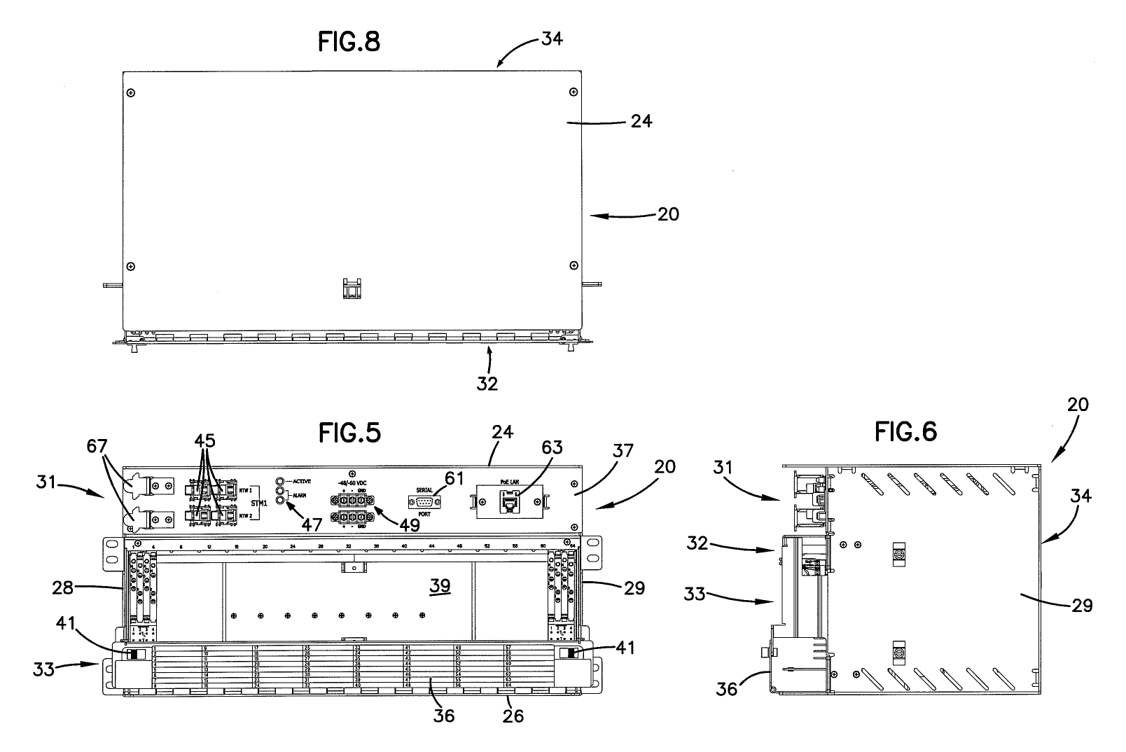

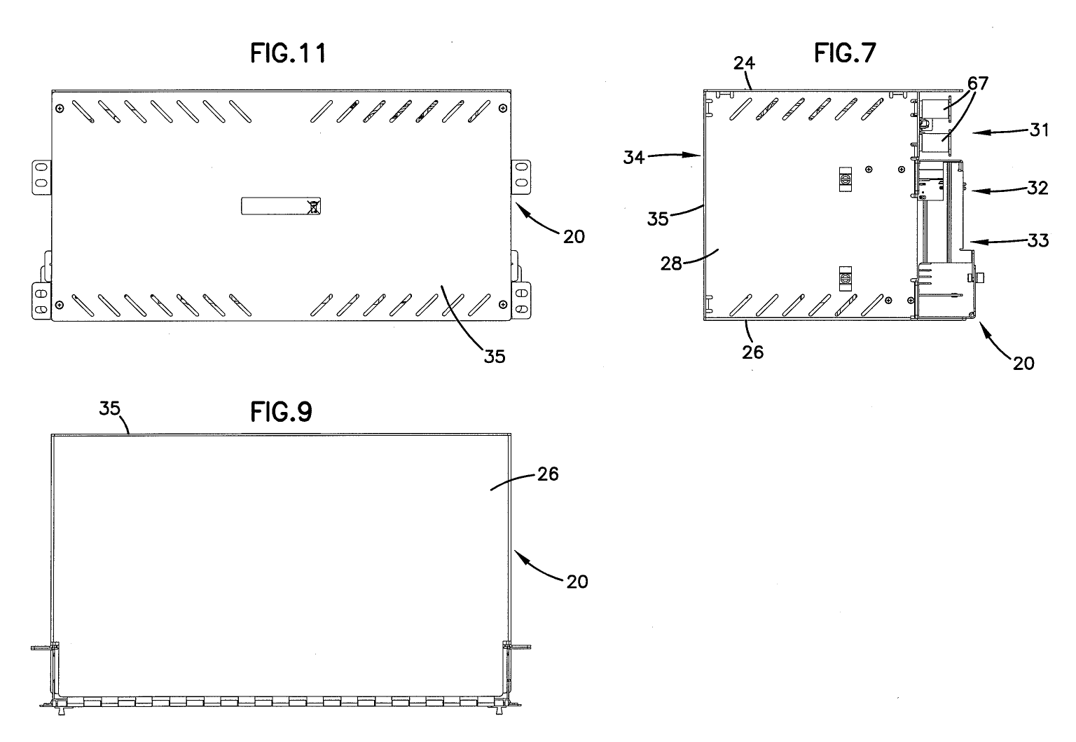

The jack mounts 22 are inserted into the chassis 20 from the front side 32 of the chassis 20. The front side 32 of the chassis includes an upper portion 31 and a lower portion 33. The upper portion 31 includes an upper front plate 37. The lower portion 33 defines the jack mount receiving portion of the chassis 20. As seen in FIGS. 6 and 7, the lower portion 33 is horizontally offset from the upper front plate 37 and extends further out toward the front 32 of the chassis 20 than the upper front plate 37.

The lower portion 33 of the front of the chassis 20 includes an opening 39 for slidably inserting or removing the jack mounts 22 into or from the chassis 20. A wire tray door 36 is connected to the bottom plate 26 adjacent the front side 32 of the housing 20. A hinge allows the door 36 to pivot between horizontal and vertical orientations. Latches 41 hold the door 36 in the vertical orientation. The door 36 allows access to the cross-connect fields of the jacks 30.

Farther into the chassis 20, a jack mounting flange 38 projects upward from the bottom plate 26. The jack mounting flange 38 defines a plurality of fastener openings 43 for allowing the jack mounts 22 to be screwed or bolted to the jack mounting flange 38. A chassis including a similar lower portion to the chassis 20 described herein, which is configured for mounting a plurality of jack mounts, is described in detail in U.S. Pat. No. 6,116,961, the entire disclosure of which is incorporated herein by reference.

The upper portion 31 of the front of the chassis 20 defines four optical adapters 45, three LED's 47 (green, yellow, and red), a power terminal block 49 (for 48VDC redundant feed), an RS232 serial port 61 (D-sub9-pin), and two Ethernet (RJ-45) connection locations 63. It should be noted that, in other embodiments, the layout of the upper portion 31 of the chassis front may be changed.

The four fiber optic adapters 45 provide the connection locations to telecommunications equipment (e.g., first telecommunications equipment 51). One of the adapter locations is for a multiplexed IN signal and another of the adapter locations is for a multiplexed OUT signal. Two of the adapter locations are for back-up, one being a multiplexed back-up IN signal and one being a multiplexed back-up OUT signal. The adapters 45 may be angled in forty-five degrees toward the left side plate 28, wherein cables may be led to cable management structures 67 located adjacent the left side plate 28.

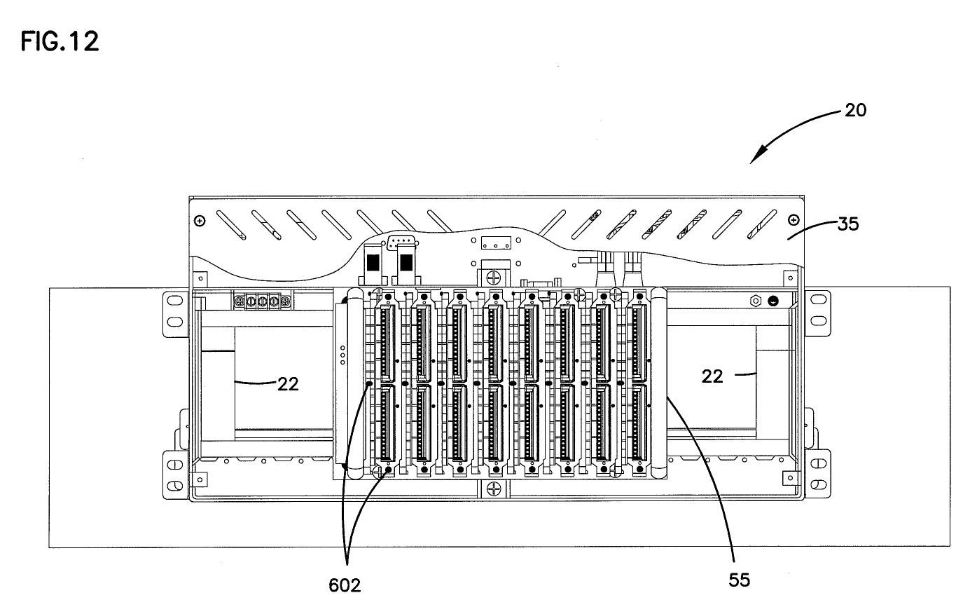

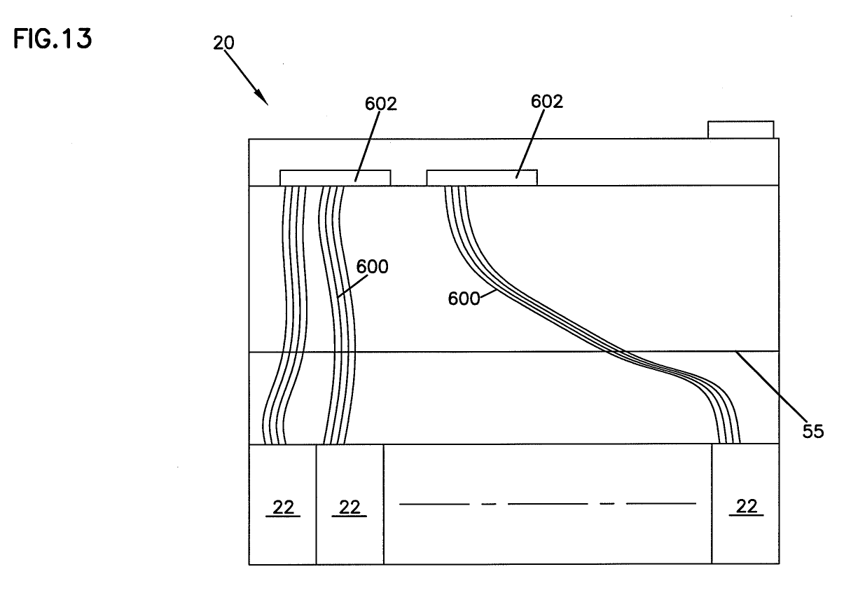

The chassis 20 is illustrated in FIG. 12, with portions of the rear plate 35 broken away to illustrate the interior of the chassis 20. The chassis 20 includes mounted therein behind the jack mounts 22 the multiplexer unit 55 (see FIG. 13). As discussed previously, in an embodiment of the ASX system 15, wherein the chassis 20 is configured to hold sixteen jack mounts 22 with four DSX jacks 30 each, the multiplexer 55 is configured to multiplex sixty-four OUT copper signals to one OUT fiber optic signal and is configured to multiplex sixty-four IN copper signals to one IN fiber optic signal. An example multiplexer suitable for use with the ASX system 15 described herein is commercially available from ADC Telecommunications, Inc., under the model number ADX 200.

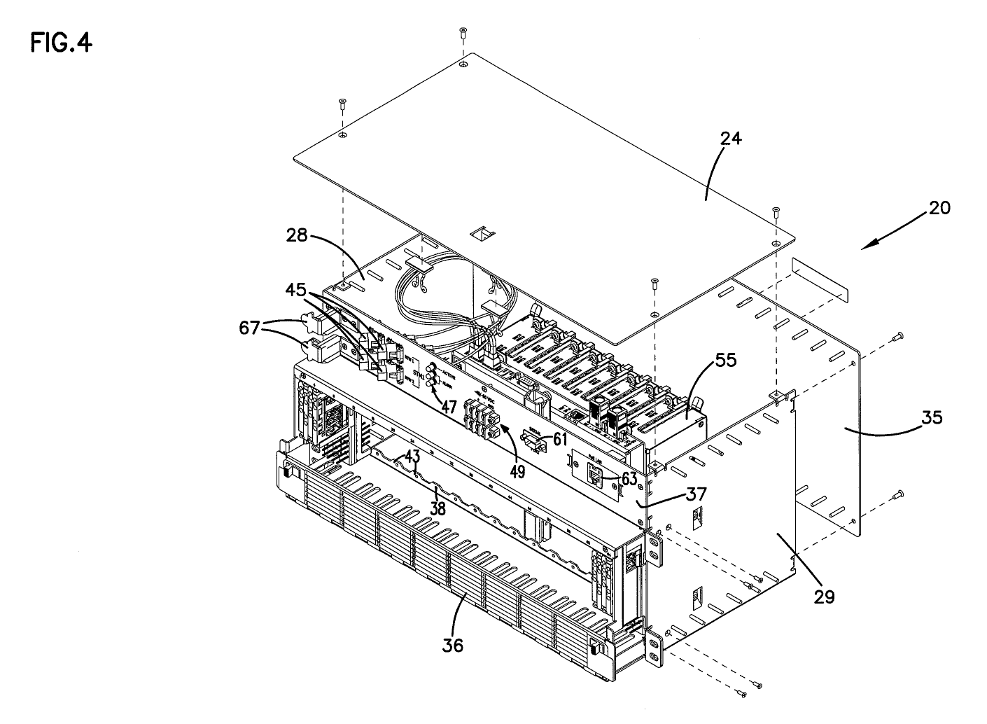

Once the copper signals from the DSX jacks 30 are multiplexed, connections between the multiplexer 55 and the front adapters 45 located on the front upper plate 37 of chassis 20 are established. As depicted in FIG. 4, connections for an IN signal, for an OUT signal, for a backup IN signal, and for a backup OUT signal, for a total of four connections is established between the multiplexer 55 and the four front adapters 45.

The chassis 20 is illustrated in an exploded view in FIG. 4 to expose the interior of the chassis 20 to show these connections between the multiplexer 55 and the adapters 45 mounted on the front upper plate 37 of the chassis 20.

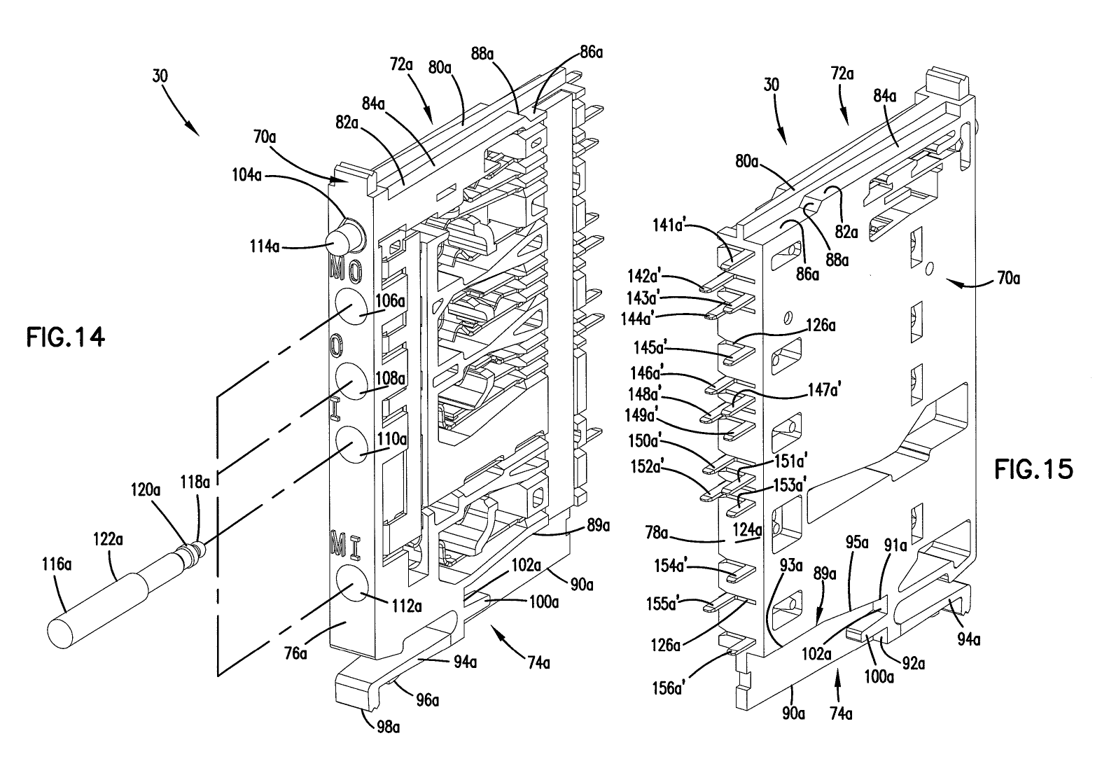

FIGS. 14 and 15 illustrate one of the DSX jacks 30 (e.g., an odd jack) in isolation from the jack mount 22. The jack 30 includes a dielectric jack body 70a. The dielectric jack body 70a includes a top side 72a and a bottom side 74a arranged and configured to slidingly interface with the jack mount 22. The jack body 70a also includes a front side 76a positioned opposite from a back side 78a. The top side 72a of the jack body 70a includes an elongated guide member 80a that extends between the front and back sides 76a and 78a of the jack body 70a. Guide surfaces 82a are positioned on opposite sides of the guide member 80a. The guide surfaces 82a include substantially parallel front and rear portions 84a and 86a. The front and rear portions 84a and 86a are interconnected by ramped portions 88a such that the front portions 84a are elevated relative to the rear portions 86a.

The bottom side 74a of the jack body 70a includes a guide member 90a that extends between the back side 78a of the jack body 70a and a transverse wall 92a. The transverse wall 92a forms a base end of a cantilevered locking member 94a that extends from the transverse wall 92a toward the front side 76a of the jack body 70a. A locking tab 96a projects downward from the locking member 94a. A gripping member 98a projects downward from a free end of the locking member 94a. The locking member 94a preferably has a resilient or elastic structure such that the locking member 94a can be flexed upward by pressing upward on the gripping member 98a. By flexing the locking member 94a, the locking member 94a can be moved between a retaining position and a non-retaining position.

The bottom side 74a additionally includes alignment members 100a that project laterally outward from opposite sides of the guide member 90a. The alignment members 100a are also connected to the transverse wall 92a and at least partially define alignment notches 102a positioned above the alignment members 100a. Guide surfaces 89a are positioned above notches 102a and include front and rear portions 91a and 93a interconnected by a ramped portion 95a. The rear portions 93a are elevated relative to the front portions 91a.

As best shown in FIG. 14, the front side 76a of the jack body 70a is generally planar and defines a light emitting diode (LED) port 104a, a monitor out port 106a, an out port 108a, an in port 110a, and a monitor in port 112a. The LED port 104a is sized for receiving an LED 114a. Each of the other ports 106a, 108a, 110a and 112a is sized to receive a standard tip-and-ring plug 116a of known dimensions. The plug 116a includes a tip contact 118a, a ring contact 120a and a cylindrical sleeve 122a.

As shown in FIG. 15, the back side 78a of the jack body 70a is formed by a generally planar surface 124a that is generally parallel with respect to the front side 76a. The planar back surface 124a defines a plurality of back slots 126a each having a generally rectangular shape.

The tip and ring springs associated with each of the ports of the jack 30 are described in detail in U.S. Pat. No. 6,116,961, the entire disclosure of which has been incorporated herein by reference.

As best shown in FIG. 15, electrically conductive springs associated with each port of the jack 30 each include portions 141a′-156a′ that extend through the slots 126a defined by the back side 78a of the jack body 70a. The portions 141a′-156a′ project outward from the back side 78a and form generally flat contact members adapted for electrically connecting the tip and ring springs of the jack 30 to a desired structure. As shown in FIG. 15, the portions 141a′-156a′ have projection lengths that vary such that the tips of the portions 141a′-156a′ are staggered. The staggered tips reduce the insertion force required to connect the jack 30 to a desired structure because all of the tips do not engage the desired structure simultaneously upon insertion.

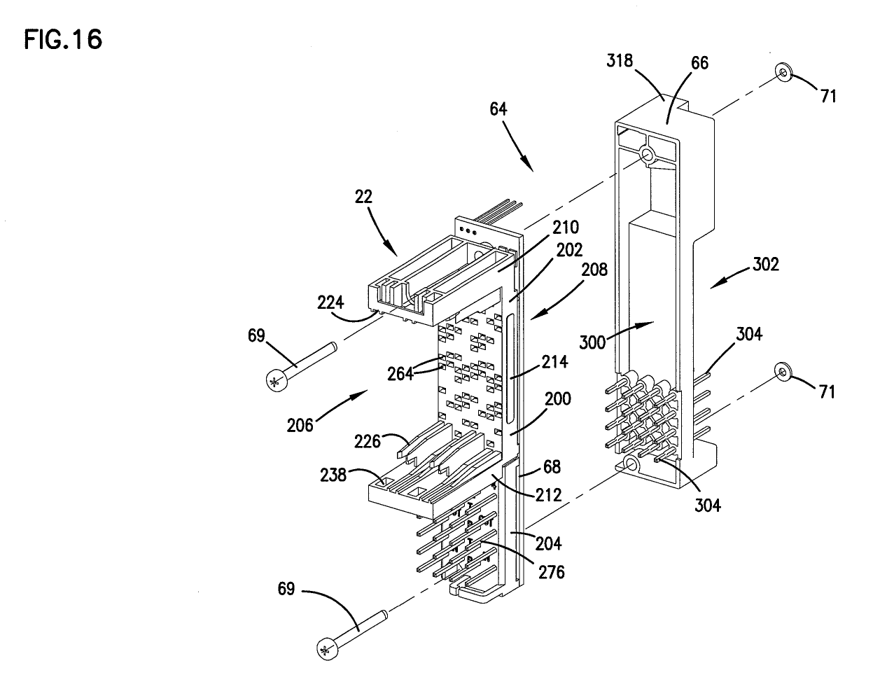

Referring now to FIGS. 16-18, a jack mount 22 is shown in isolation from the chassis 20 with the odd jacks (e.g., jack 30) and the even jacks removed. Generally, the jack mount 22 includes a mounting body 200 made of a dielectric material. The mounting body 200 includes a jack receiving piece 202 that can be detachably connected to a cross-connect piece 204. As will be described in greater detail below, the jack receiving piece 202 is adapted for housing or holding the jacks, while the cross-connect piece 204 is adapted for providing cross-connects between jacks.

The jack receiving piece 202 of the mounting body 200 includes a front side 206 positioned opposite from a back side 208. The piece 202 also includes spaced-apart and substantially parallel top and bottom supports 210 and 212 that extend generally between the front and back sides 206 and 208. The top and bottom supports 210 and 212 are interconnected by a back wall 214 of the jack receiving piece 202. The top support 210, the bottom support 212 and the back wall 214 cooperate to define a jack mounting region or recess that opens outward toward the front side 206 of the upper piece 202.

Jack mounting region defines top and bottom channels 224 and 226 respectively formed on the top support 210 and the bottom support 212. The top and bottom channels 224 and 226 are configured to respectively complement the top and bottom sides 72a and 74a of the jacks 30.

The jack 30 is mounted by inserting the rear ends of the guide members 80a and 90a respectively within the top and bottom channels 224 and 226. The jack 30 is then pushed inward toward the back wall 214 of the jack receiving piece 202 causing the guide members 80a and 90a to respectively slide along the top and bottom channels 224 and 226. When the jack 30 has been fully inserted into the jack receiving piece 202, the locking tab 96a of the resilient locking member 94a snaps within a hole 238 defined by the bottom support 212. To remove the jack 30 from the jack mount 22, the resilient locking member 94a is flexed from a retaining position to a non-retaining position such that the locking tab 96a is displaced from the hole 238. The jack 30 can then be manually pulled out from the jack receiving piece 202.

The top and bottom channels 224, 226 of mounting locations have been designed in coordination with the top and bottom sides of the jacks 30 in order to provide a keying function. For example, the jack 30 can only be mounted in the jack mount 22 if it is oriented in an upright position and is inserted into either one of the jack mounting locations.

As shown in FIG. 16, jack mounts 22 each include a corresponding pattern or array of openings 264 defined through the back wall 214 of the jack receiving piece 202 of the mounting body 200. The openings 264 are configured to receive the spring ends 141a′-156a′ that project outward from the back side 78a of each jack 30.

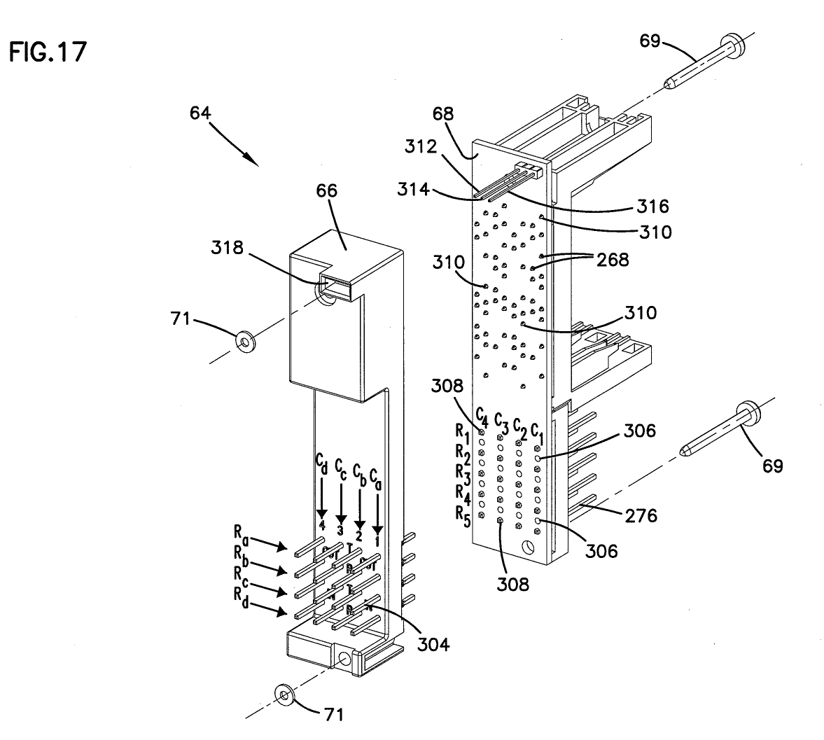

The openings 264 and 266 extend completely through the back wall 214. Connection pins 268 (e.g., insulation displacement contacts) (see FIG. 17) are mounted within each of the openings 264 and 266.

When the jacks 30 are mounted within the jack mount 22, the spring extensions 141a′-156a′ fit within the openings 264 and are compressed between opposing contact members of the connection pins 268 such that the spring contacts 141a-156a are electrically connected to the pins 268. Please refer to U.S. Pat. No. 6,116,961, the entire disclosure of which has been incorporated herein by reference, for further detail regarding the connections between the connection pins 268 and the spring extensions 141a′-156a′ of the jacks 30.

Still referring to FIGS. 16 and 17, the cross-connect piece 204 of the mounting body 200 is adapted for providing cross-connections between jacks. For example, four columns (C₁-C₄) and five rows (R₁-R₅) of wire termination members 276 (e.g., wire wrap members or posts) are shown projecting outward from a front face 278 of the piece 204. It will be appreciated that the removability of the cross-connect piece 204 from the jack receiving piece 202 is significant because different types of wire termination members or contacts can be used to provide cross-connections. For example, for certain applications, it may be desired to use insulation displacement connectors (IDC) for providing cross-connections between jacks. By using cross-connect pieces 204 that are separate from the jack mounting portion 202, cross-connect pieces having different types of connectors can be used with the common base to enhance manufacturing efficiency. While wire wrap members and insulation displacement connectors have been specifically described, it will be appreciated that other types of connectors could also be used.

FIGS. 16 and 17 illustrate also the dielectric support 66 of the rear interface assembly 64. The dielectric support 66 includes a front side 300 and a back side 302. As shown in FIG. 17, the rear interface assembly 64 also includes four columns (Cₐ-C_{d}) and four rows (Rₐ-R_{d}) of wire termination members 304 press fit within holes defined by the dielectric support 66. The wire termination members 304 are shown as wire wrap members. However, it will be appreciated that other types of wire termination members such as insulation displacement connectors could also be used.

Referring to FIG. 17, the wire termination members 304 are adapted to contact plated through-holes 306 in a circuit board 68. Similarly, the wire termination members 276 of the jack mount 22 connect with plated through-holes 308 in the circuit board 68. The plated through-holes 306 are oriented in rows that are positioned between rows R₁-R₅. The circuit board 68 also includes a plurality of additional plated through-holes 310 positioned to make electrical contacts with the connector pins 268 that project outward from the back wall 214 of the jack mount upper piece 202.

The dielectric support 66 of the rear interface assembly 64 defines a protective receptacle 318 in which a voltage lead 312, a return lead 314 and a sleeve ground lead 316 are mounted.

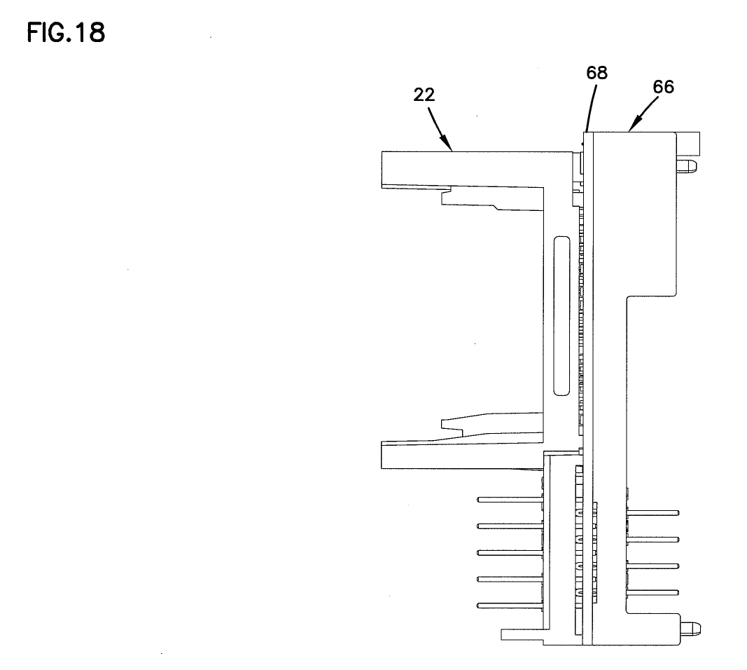

Referring to FIG. 18, when the jack mount 22 is assembled, the printed circuit board 68 is positioned between the jack receiving portion and the dielectric support 66. The circuit board 68 includes a plurality of circuit paths for electrically connecting selected ones of the connection pins 268 to the receptacle leads 312, 314 and 316, to the wire termination members 304 of the rear interface assembly 64, and to the cross-connect wire termination members 276. The single circuit board 68 is adapted for connecting all four jacks on a jack mount to the leads 312, 314 and 316, and to the their corresponding columns of rear interface wire termination members 304 and cross-connect wire termination members 276. When the jacks are removed from the jack mount 22, the jacks are disconnected from the circuit board 68.

As shown in FIGS. 16 and 17, the circuit board 68, the jack receiving portion and the dielectric support 66 define coaxially aligned openings sized to receive fasteners 69 (e.g., bolts or screws) for connecting the pieces together. The fasteners 69 extend through captivation washers 71 that are press-fit over the fasteners 69. The captivation washers 71 and the fasteners 69 hold the jack mount 22, the circuit board 68 and the dielectric support 66 together after assembly and inhibit the pieces from being unintentionally pulled apart prior to connection to the chassis 20. The assembly is connected to the chassis 20 by threading the fasteners within holes defined by the chassis 20.

In use of the jack assembly, columns C₁-C₄ of cross-connect wire termination member 276 are connected to jacks positioned in the mounting locations. The wire termination members 276 of row R₁ are tracer lamp contacts (TL), the wire termination members 276 of row R₂ are cross-connect tip-out contacts (XTO), the wire termination members 276 of row R₃ are cross-connect ring-out contacts (XRO), the wire termination members 276 of row R₄ are cross-connect tip-in contacts (XTI), and the wire termination members 276 of row R₅ are cross-connect ring-in contacts (XRI).

Columns Cₐ-C_{d} of the IN/OUT termination members 304 are respectively in electrical contact with jacks inserted within jack mounting locations. The wire termination members 304 of row Rₐ are tip-out contacts (TO), the wire termination members 304 forming row R_{b} are ring-out contacts (RO), the wire termination members 304 forming row R_{c} are tip-in contacts (TI), and the wire termination members 304 forming row R_{d} are ring-in contacts (RI).

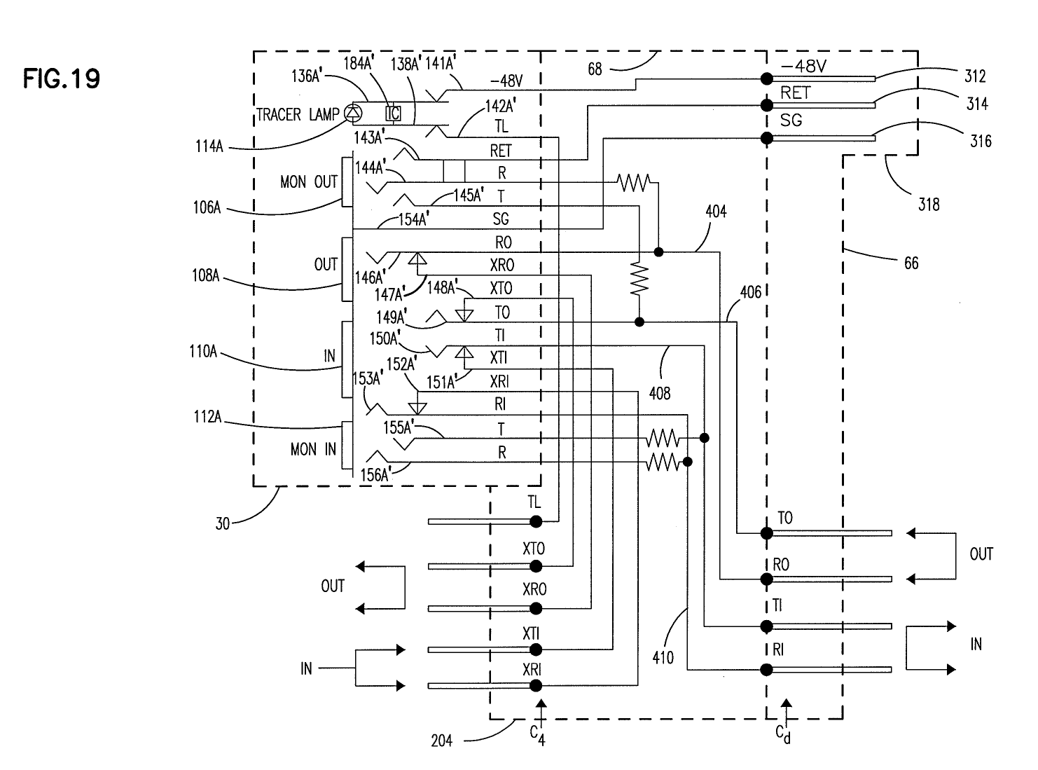

FIG. 19 is a circuit diagram illustrating the electrical connections made when one of the jacks 30 is inserted within one of the jack mounting locations of the jack mounts 22.

Referring to FIG. 19, the voltage spring 141a′ is electrically connected to an energized contact point (e.g., the voltage lead 312) for illuminating the LED. The tracer lamp spring 142a′ is connected to the tracer lamp contact TL of column C₄. The return spring 143a′ is connected to the return lead 314. The shield ground spring 154a′ is connected to the shield ground lead 316. The out ring spring 146a′ is connected to the ring-out contact RO by circuit path 404. The ring normal spring 147a′ is connected to the cross-connect ring-out contact XRO of column C₄. The tip normal spring 148a′ is connected to the cross-connect tip-out contact XTO of column C₄. Tip spring 149a′ is connected to the tip-out contact TO of column C_{d} by circuit path 406. The monitor out ring spring 144a′ is connected to circuit path 404, and the monitor out tip spring 145a′ is connected to circuit path 406. Tip spring 150a′ is connected to the tip-in contact TI of column C_{d} by circuit path 408. Tip normal spring 151a′ is connected to the cross-connect tip-in contact XTI of column C₄, and ring normal spring 152a′ is electrically connected to the cross-connect ring-in contact XRI of column C₄. Ring spring 153a′ is connected to the ring-in RI contact of column C_{d} by circuit path 410. Tip spring 155a′ is connected to circuit path 408, while ring spring 156a′ is connected to circuit path 410.

Cross-connection of a signal from another jack arrives as an IN signal from cross-connect tip-in and ring-in contacts XTI and XRI of column C₄. With no plug inserted within the in port 110a, the IN signal is output at the tip-in and ring-in contacts TI and RI of column C_{d}.

By inserting a plug within the in port 110a, the IN signal from a cross-connected jack can be interrupted and a signal from the inserted plug can be outputted at points TI and RI. Similarly, by inserting a plug within the out port 108a, the OUT signal from contact points TO and RO is interrupted and may be outputted to the tip-and-ring contacts of the plug inserted within the out port 108a.

Frequently it is desirable to be able to monitor OUT signals arriving through contacts TO and RO without interrupting the OUT signals. To accomplish this, a plug is inserted into the monitor port 106a. On this occurrence, the plug is able to tap into the OUT signals being transmitted through circuit paths 404 and 406. Additionally, when the plug is inserted into the port 106a, the return spring 143a′ is biased upward into contact with the second lead 138a′ of the tracer lamp 114a. The electrical connection between the second lead 138a′ and the return spring 143a′ connects the LED circuit to the return line 314 thereby illuminating the LED. Integrated circuit chip 184a′ controls flashing of the LED 114a as is conventionally known in the art. In addition to activating the LED, insertion of a plug into the monitor port 106a also grounds the tracer lamp line TL causing illumination of a LED on a jack to which the present jack is cross-connected.

At times it is also desired to be able to monitor signals on the IN line without interrupting the IN line signal. To accomplish this, a plug is inserted into the monitor in port 112a. When the plug is inserted into the port 112a, the plug taps into the in signal being transmitted through circuit path 408 between contacts XTI and TI, and circuit path 410 between contacts XRI and RI.

The jack mount 22 is described in greater detail in U.S. Pat. No. 6,116,961, the entire disclosure of which has been incorporated herein by reference.

As discussed previously, the tip-out contacts TO, the ring-out contacts RO, the tip-in contact TI, and the ring-in contacts RI are electrically connected to the multiplexer unit 55 located within the chassis 20. Please see FIG. 2. Each of the tip-out contacts TO, ring-out RO contacts, tip-in contacts TI, and ring-in contacts RI are connected with wires 600 to insulation displacement contacts 602 (i.e., punch-downs) located at the rear of the multiplexer unit 55 (please see FIG. 12). The wiring is illustrated diagrammatically in FIG. 13, wherein the chassis is shown with the top plate 24 removed to expose the interior of the chassis 20.

In the embodiment of the chassis 20 depicted, wherein the chassis 20 is configured to house sixty-four DSX jacks 30, the multiplexer 55 includes 256 insulation displacement contacts 602 located in the rear of the multiplexer. Each of the sixty-four DSX jacks 30 includes a tip-out contact TO, a ring-out RO contact, a tip-in contact TI, and a ring-in contact RI that are connected to the insulation displacement contacts 602 of the multiplexer 55 for a total of 256 wire terminations.

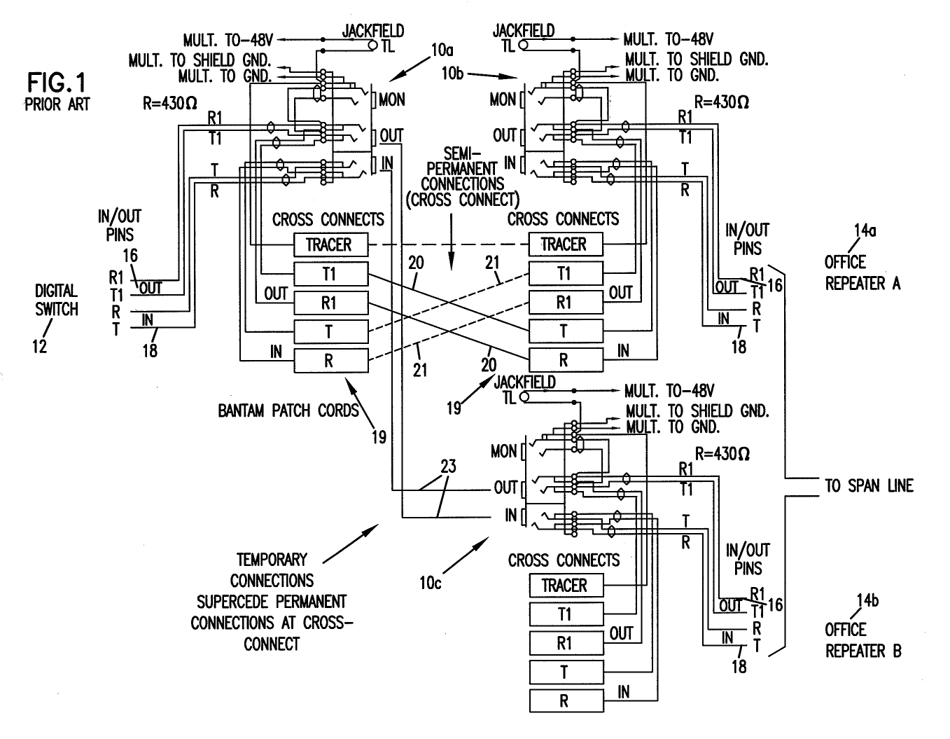

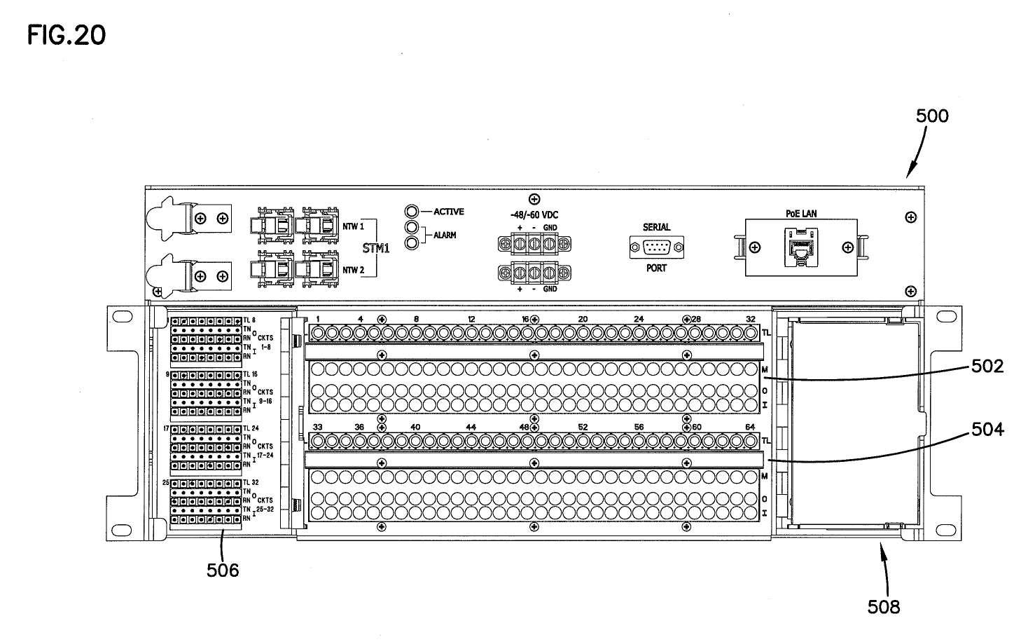

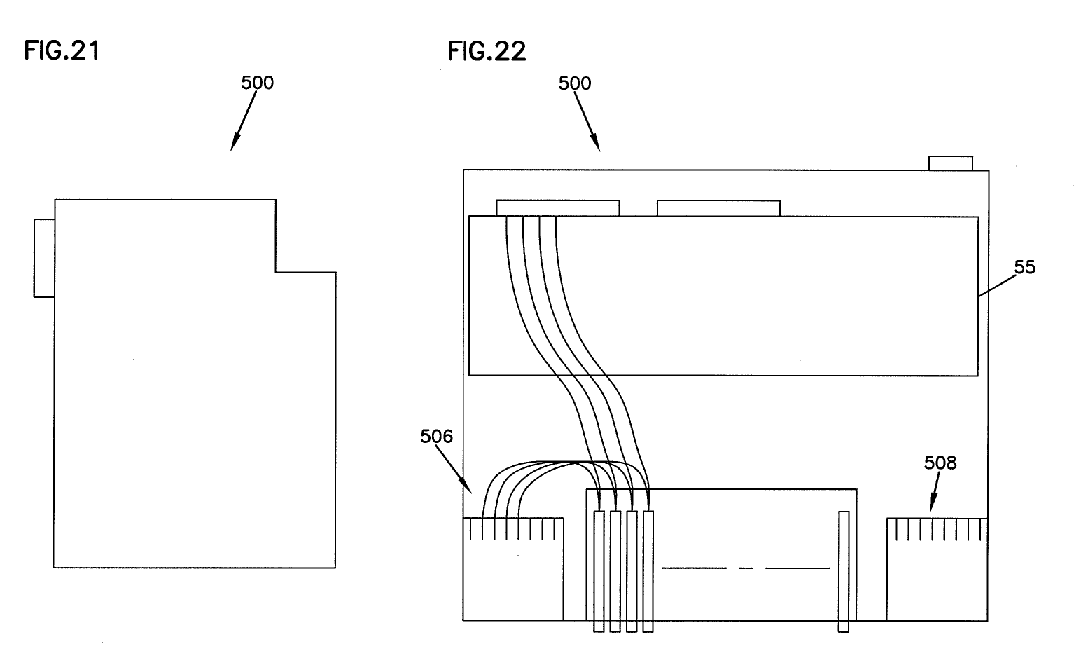

FIGS. 20-22 illustrate another embodiment of a chassis 500 configured to house the ASX system 15 diagrammatically shown in FIG. 2. The chassis 500 is similar to the chassis 20 illustrated in FIGS. 1-13 except that the chassis 500 includes a different jack mount configuration. As shown in FIG. 20, the chassis 500 is configured to receive an upper row of jacks 502 and a lower row of jacks 504 with the cross-connect fields 506, 508 being located at the sides of the jacks. The upper jacks 502 and the lower jacks 504 are not individually removable as in the jacks 30 shown in FIGS. 14 and 15. This jack mounting configuration, however, allows for a greater jack density and only requires a three-rack-unit of space for the chassis 500 (3RU), wherein the chassis 20 requires a four-rack-unit of space (4RU). A similar jack assembly to that shown in FIGS. 20-22 is described in greater detail in U.S. Application Publication No. 2003/0231744 and U.S. Pat. Nos. 6,422,902; 6,503,105; and 6,543,626, the entire disclosures of which are incorporated herein by reference.

The wiring within the chassis 500 is shown in FIG. 22. As shown in FIG. 22, the wiring is similar to the wiring of the chassis 20 shown in FIGS. 1-13, wherein the tip-out contact TO, the ring-out RO contact, the tip-in contact TI, and the ring-in contact RI of the jacks are connected with wire-wraps to insulation displacement contacts located at the rear of the multiplexer unit 55. Also, similar to that shown in FIG. 4, once the signals are multiplexed, the connections between the multiplexer 55 and the front adapters 45 located on a front upper plate of the chassis 500 are established. Connections for an IN signal, an OUT signal, a backup IN signal, and a backup OUT signal, for a total of four connections are established between the multiplexer 55 and the four front adapters 45. As in the chassis 20, the four adapters are accessible from the front of the chassis 500 for connection to telecommunications equipment.

Having described preferred inventive aspects and embodiments of the present disclosure, modifications and equivalents of the disclosed concepts may readily occur to one skilled in the art.

1. A telecommunications system comprising:
a chassis having a front side and a rear side;
a plurality of jacks mounted to the chassis, each jack including an IN port, an OUT port and a MONITOR port;
a cross-connect panel including an array of cross-connect connection locations accessible from the front side of the chassis; and
an optical multiplexer housed within the chassis, the optical multiplexer electrically connected to the plurality of jacks by circuitry within the chassis, the multiplexer configured to multiplex a plurality of IN electrical signals that are going away from the jacks toward a piece of telecommunications equipment to an IN optical signal and configured to split an OUT optical signal that is going away from the piece of telecommunications equipment toward the jacks to a plurality of OUT electrical signals;
wherein the IN electrical signals and the OUT electrical signals can be monitored by inserting plugs into the MONITOR ports of the jacks.

2. A telecommunications system according to claim 1, wherein each jack includes a first set of spring contacts positioned adjacent the IN port, a second set of spring contacts positioned adjacent OUT port, and a third set of spring contacts positioned adjacent the MONITOR port, wherein the chassis further includes an IN/OUT panel including an array of IN and OUT connection locations positioned within the chassis, the first set of spring contacts and the second set of spring contacts being electrically connected to the IN/OUT panel and the cross-connect panel and the third set of spring contacts being electrically connected to corresponding ones of at least one of the first and second set of spring contacts.

3. A telecommunications system according to claim 2, wherein the electrical connections among the first, second, and third set of spring contacts, the IN and OUT connection locations, and the cross-connect connection locations are established via a printed circuit board.

4. A telecommunications system according to claim 2, wherein the first, second, and third sets of spring contacts include tip and ring springs, the tip springs configured to make electrical contact with tip contacts of plugs when the plugs are inserted into the ports, the ring springs configured to make electrical contact with ring contacts of the plugs when the plugs are inserted within the ports.

5. A telecommunications system according to claim 1, wherein the jacks are each separately removable from the chassis.

6. A telecommunications system according to claim 1, wherein the chassis includes an optical connection location at the front of the chassis for outputting a multiplexed IN optical signal to the piece of telecommunications equipment and an optical connection location at the front of the chassis for inputting an OUT optical signal from the piece of telecommunications equipment to be split into a plurality of electrical signals by the multiplexer, the optical connection locations defining fiber optic adapters.

7. A telecommunications system according to claim 6, wherein the IN ports, the OUT ports, the MONITOR ports, the cross-connect connection locations, and the optical connection locations are positioned adjacent the front of the chassis.

8. A telecommunications system according to claim 1, wherein each jack defines the IN port, the OUT port, and two MONITOR ports, the two MONITOR ports including a MONITOR IN port for monitoring IN signals and a MONITOR OUT port for monitoring OUT signals.

9. A telecommunications system according to claim 1, wherein the chassis includes a right side and a left side, the cross-connect panel defining a first array of cross-connect connection locations positioned adjacent the right side and a second array of cross-connect connection locations positioned adjacent the left side, the plurality of jacks being positioned adjacent the front of the chassis in between the first and second arrays of cross-connect connection locations.

10. A telecommunications system according to claim 1, wherein the chassis further includes an IN/OUT panel including an array of IN and OUT connection locations positioned within the chassis, the optical multiplexer being electrically connected to the IN/OUT panel at the IN and OUT connection locations.

11. A telecommunications system according to claim 10, wherein the multiplexer includes a plurality of insulation displacement contacts and the IN and OUT connection locations include wire-wrap termination pins, the electrical connection between the multiplexer and the IN/OUT panel being established by cables going between the insulation displacement contacts and the wire-wrap termination pins.

12. A telecommunications system according to claim 1, wherein the chassis includes sixty-four jacks and requires a three-rack-unit of space for mounting the chassis to a telecommunications rack.

13. A telecommunications system according to claim 1, wherein the chassis includes sixty-four jacks and requires a four-rack-unit of space for mounting the chassis to a telecommunications rack.

14. A telecommunications system according to claim 1, wherein the optical multiplexer is configured to multiplex sixty-four IN electrical signals to one IN optical signal and is configured to split one OUT optical signal into sixty-four OUT electrical signals.

15. A telecommunications system according to claim 1, wherein the plurality of jacks are mounted on jack mounts slidably removable from the front of the chassis, each jack mount including a jack mount body with guide tracks for receiving at most four jacks.

16. A telecommunications system according to claim 1, wherein each jack includes an LED having first and second electrical leads, wherein the cross-connect connection locations include a tracer lamp contact and wherein the first lead is electrically connected to a power source and the second lead is connected to the tracer lamp contact.

17. A telecommunications system according to claim 1, wherein the chassis includes a pivotal door for selectively covering the cross-connect connection locations.

18. A digital cross-connect system comprising:
a chassis having a front side and a rear side;
a plurality of IN ports, a plurality of OUT ports and a plurality of MONITOR ports accessible from the front of the chassis;
a cross-connect panel located adjacent the front of the chassis, the cross-connect panel including a plurality of cross-connect connection locations accessible from the front of the chassis;
an optical multiplexer housed within the chassis; and
a first optical connection location and a second optical connection location adjacent the front of the chassis, wherein an optical OUT signal converted to an electrical OUT signal by the optical multiplexer is input at the first optical connection location and an electrical IN signal converted to an optical IN signal by the optical multiplexer is output at the second optical connection location;
wherein the electrical IN signal can be interrupted by inserting a plug into one of the plurality of IN ports and the electrical OUT signal can be interrupted by inserting a plug into one of the plurality of OUT ports, and wherein at least one of the electrical IN signal and the electrical OUT signal can be monitored by inserting a plug into one of the plurality of MONITOR ports.

19. A telecommunications system comprising:
a chassis having a front side and a rear side;
a plurality of jacks mounted to the chassis, each jack including an IN port, an OUT port and a MONITOR port, a first set of spring contacts positioned adjacent the IN port, a second set of spring contacts positioned adjacent OUT port, a third set of spring contacts positioned adjacent the MONITOR port;
an IN/OUT panel including an array of IN and OUT connection locations positioned within the chassis;
a cross-connect panel including an array of cross-connect connection locations accessible from the front side of the chassis;
the first set of spring contacts and the second set of spring contacts being electrically connected to the IN/OUT panel and the cross-connect panel;
the third set of spring contacts being electrically connected to corresponding ones of at least one of the first and second set of spring contacts such that signals transmitted through at least one of the first and second set of spring contacts can be monitored by inserting plugs into the MONITOR ports; and
an optical multiplexer housed within the chassis, the multiplexer electrically connected to the IN/OUT panel at the IN and OUT connection locations, the multiplexer configured to multiplex a plurality of IN electrical signals that are going away from the jacks toward a piece of telecommunications equipment to an IN optical signal and configured to split an OUT optical signal that is going away from a piece of telecommunications equipment toward the jacks to a plurality of OUT electrical signals.

20. A telecommunications system according to claim 19, wherein the chassis includes an optical connection location at the front of the chassis for outputting a multiplexed IN optical signal to the piece of telecommunications equipment and an optical connection location at the front of the chassis for inputting an OUT optical signal from the piece of telecommunications equipment to be split into a plurality of electrical signals by the multiplexer.
